(19) United States
(12) Patent Application Publication
(10) Pub. No.: US 2024/0215373 A1
(43) Pub. Date: Jun. 27, 2024

(54) LIGHT EMITTING DIODE DISPLAY DEVICE

(71) Applicant: LG Display Co., Ltd, Seoul (KR)

(72) Inventor: Yeon-Suk KANG, Paju-si (KR)

(73) Assignee: LG Display Co., Ltd, Seoul (KR)

(21) Appl. No.: 18/467,867

(22) Filed: Sep. 15, 2023

(30) Foreign Application Priority Data
Dec. 26, 2022 (KR) 10-2022-0184569

(51) Int. Cl. H10K 59/38; H10K 59/80

(52) U.S. Cl. CPC H10K 59/38; H10K 59/879; H10K 59/8792

(57) ABSTRACT

An organic light emitting diode display device includes a substrate having first, second and third subpixels; a light emitting diode in each of the first, second and third subpixels on the substrate; a black matrix in a border region between the first, second and third subpixels on the light emitting diode; first, second and third color filters in the first, second and third subpixels, respectively, on the light emitting diode, a thickness of each of the first, second and third color filters smaller than a thickness of the black matrix; and a microlens on each of the first, second and third color filters.

### CROSS-REFERENCE TO RELATED APPLICATION

The present application claims the priority of Korean Patent Application No. 10-2022-0184569 filed on Dec. 26, 2022, which is hereby incorporated by reference in its entirety.

### BACKGROUND

### Field of the Disclosure

The present disclosure relates to a display device, and more particularly, to an organic light emitting diode display device including a color filter layer and a microlens.

### Description of the Background

As an information society progresses, a need for a display device displaying an image increases. Various display devices such as a liquid crystal display (LCD) device and an organic light emitting diode (OLED) display device have been utilized.

Recently, with the advent of an information-oriented society and as the interest in information displays for processing and displaying a massive amount of information and the demand for portable information media have increased, a display field has rapidly advanced. Thus, various light and thin flat panel display devices have been developed and highlighted.

Among the various flat panel display devices, an organic light emitting diode (OLED) display device is an emissive type device and does not include a backlight unit used in a non-emissive type device such as a liquid crystal display (LCD) device. As a result, the OLED display device has a light weight and a thin profile and has advantages in a viewing angle, a contrast ratio and a power consumption to be applied to various fields.

A head mounted display (HMD) including an organic light emitting display device has been recently developed. The HMD is a glass type monitor for a virtual reality (VR) or an augmented reality (AR) which is worn as a shape of a glass or a helmet such that a focus is formed at a point having a short distance from a user's eye.

The OLED display device having a small size and a high resolution applied to the HMD may be formed through a semiconductor process based on a wafer. In the semiconductor process, an anode is disposed on an insulating layer covering a thin film transistor on a wafer, and an emitting layer and a cathode are disposed on the anode. Further, an encapsulating layer, a color filter layer and a microlens array are sequentially disposed on the cathode.

Since an area of each of red, green and blue subpixels decreases as a resolution increases, a thickness of a last one of the red, green and blue color filters increases, and a step difference between the red, green and blue color filters increases. When the microlens array is formed on the red, green and blue color filters having a relatively great step difference, an organic material for the microlens array may flow along the step difference during a heat treatment step. As a result, a shape of a microlens is not maintained to be planarized.

### SUMMARY

Accordingly, the present disclosure is directed to a display device that substantially obviates one or more of problems due to the limitations and disadvantages of the related art.

More specifically, the present disclosure is to provide an organic light emitting display device where a step difference between color filters is reduced, a shape of a microlens is maintained and an abnormal emission is reduced or minimized by disposing a black matrix higher than the color filter between the adjacent color filters.

In addition, the present disclosure is to provide an organic light emitting diode display device where a step difference between color filters is reduced, a shape of a microlens is maintained and a fabrication process is simplified by forming one color filter higher than the other color filters.

Additional features and advantages of the disclosure will be set forth in the description which follows, and in part will be apparent to those skilled in the art from the description or may be learned by practice of the disclosure. These and other advantages of the disclosure may be realized and attained by the structure particularly pointed out in, or derivable from, the written description, claims hereof, and the appended drawings.

To achieve these and other advantages and in accordance with the purpose of the present disclosure, as embodied and broadly described herein, an organic light emitting diode display device includes a substrate having first, second and third subpixels; a light emitting diode in each of the first, second and third subpixels on the substrate; a black matrix in a border region between the first, second and third subpixels on the light emitting diode; first, second and third color filters in the first, second and third subpixels, respectively, on the light emitting diode, a thickness of each of the first, second and third color filters smaller than a thickness of the black matrix; and a microlens on each of the first, second and third color filters.

In another aspect, an organic light emitting diode display device includes: a substrate having first, second and third subpixels; a light emitting diode in each of the first, second and third subpixels on the substrate; first, second and third color filters in the first, second and third subpixels, respectively, on the light emitting diode; and a microlens on each of the first, second and third color filters, wherein a thickness of one of the first, second and third color filters is greater than a thickness of others of the first, second and third color filters.

It is to be understood that both the foregoing general description and the following detailed description are explanatory and by way of examples and are intended to provide further explanation of the disclosure as claimed without limiting its scope.

### BRIEF DESCRIPTION OF THE DRAWINGS

The accompanying drawings, which are included to provide a further understanding of the disclosure and are incorporated in and constitute a part of this specification, illustrate aspects of the disclosure and together with the description serve to explain the principles of the disclosure.

In the drawings:

FIG. 1 is a view showing an organic light emitting diode display device according to a first aspect of the present disclosure;

FIG. 2 is a plan view showing an organic light emitting diode display device according to a first aspect of the present disclosure;

FIG. 3 is a cross-sectional view taken along line III-III of FIG. 2;

FIGS. 4A, 4B and 4C are views showing spectrums of lights emitted from red, green and blue subpixels, respectively, of an organic light emitting diode display device according to a first aspect of the present disclosure;

FIG. 5 is a cross-sectional view showing an organic light emitting diode display device according to a second aspect of the present disclosure;

FIG. 6 is a cross-sectional view showing an organic light emitting diode display device according to a third aspect of the present disclosure; and

FIG. 7 is a cross-sectional view showing an organic light emitting diode display device according to a fourth aspect of the present disclosure.

### DETAILED DESCRIPTION

Advantages and features of the present disclosure, and implementation methods thereof will be clarified through following example aspects described with reference to the accompanying drawings. The present disclosure may, however, be embodied in different forms and should not be construed as limited to the example aspects set forth herein. Rather, these example aspects are provided so that this disclosure may be sufficiently thorough and complete to assist those skilled in the art to fully understand the scope of the present disclosure. Further, the protected scope of the present disclosure is defined by claims and their equivalents.

Hereinafter, an organic light emitting diode display device according to various example aspects of the present disclosure will be described in detail with reference to the accompanying drawings.

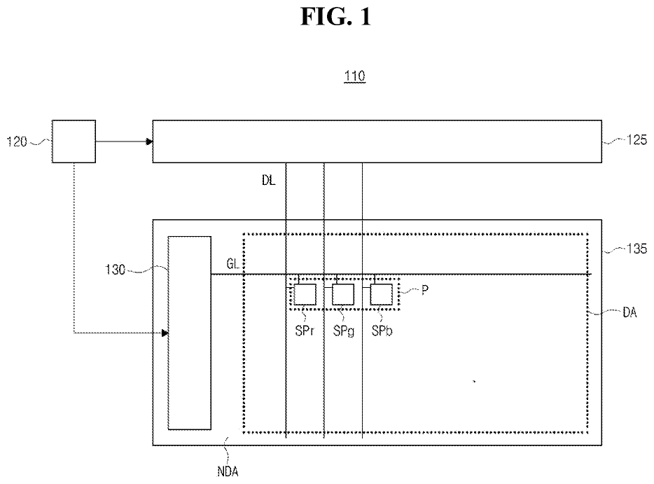

FIG. 1 is a view showing an organic light emitting diode display device according to a first aspect of the present disclosure.

In FIG. 1, an organic light emitting diode (OLED) display device 110 according to a first aspect of the present disclosure includes a timing controlling unit 120, a data driving unit 125, a gate driving unit 130 and a display panel 135.

The timing controlling unit 120 generates an image data, a data control signal and a gate control signal using an image signal and a plurality of timing signals including a data enable signal, a horizontal synchronization signal, a vertical synchronization signal and a clock signal transmitted from an external system such as a graphic card or a television system. The timing controlling unit 120 transmits the image data and the data control signal to the data driving unit 125 and transmits the gate control signal to the gate driving unit 130.

The data driving unit 125 generates a data signal (data voltage) using the data control signal and the image data transmitted from the timing controlling unit 120 and supplies the data signal to a data line DL of the display panel 135.

The gate driving unit 130 generates a gate signal (gate voltage) using the gate control signal transmitted from the timing controlling unit 120 and supplies the gate signal to a gate line GL of the display panel 135. In addition, the gate driving unit 130 may generate an emission signal according to a structure of each subpixel SPr, SPg and SPb and may supply the emission signal to the display panel 135.

The gate driving unit 130 may have a gate in panel (GIP) type to be formed in a non-display area NDA of a substrate of the display panel 135 having the gate line GL, the data line DL and a pixel P.

The display panel 135 includes a display area DA at a central portion thereof and a non-display area NDA surrounding the display area DA. The display panel 135 displays an image using the gate signal and the data signal. For displaying an image, the display panel 135 includes a plurality of pixels P, a plurality of gate lines GL and a plurality of data lines DL in the display area DA.

Each of the plurality of pixels P may include red, green and blue subpixels SPr, SPg and SPb. The gate line GL and the data line DL cross each other to define the red, green and blue subpixels SPr, SPg and SPb, and each of the red, green and blue subpixels SPr, SPg and SPb is connected to the gate line GL and the data line DL.

Although not shown, each of the red, green and blue subpixels SPr, SPg and SPb may include a plurality of thin film transistors such as a switching thin film transistor and a driving thin film transistor, a storage capacitor and a light emitting diode.

A structure of the subpixel of the OLED display device 110 will be described with reference to a drawing.

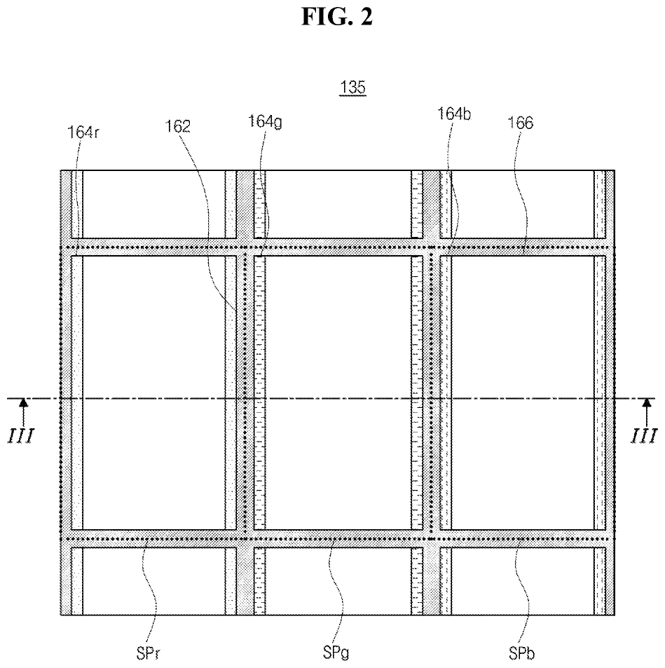

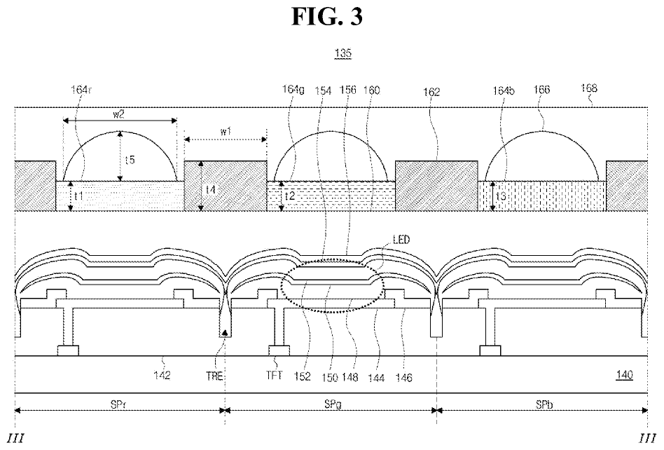

FIG. 2 is a plan view showing an organic light emitting diode display device according to a first aspect of the present disclosure, and FIG. 3 is a cross-sectional view taken along line III-III of FIG. 2.

In FIGS. 2 and 3, the display panel 135 of the OLED display device 110 according to a first aspect of the present disclosure includes the red, green and blue subpixels SPr, SPg and SPb, and each of the red, green and blue subpixels SPr, SPg and SPb includes a thin film transistor TFT and a light emitting diode LED. For example, the OLED display device 110 has a top emission type.

The thin film transistor TFT is disposed in each of the red, green and blue subpixels SPr, SPg and SPb on a substrate 140.

The substrate 140 may include a glass, a plastic or a semiconductor material. For example, the substrate 140 may be a wafer including single crystalline silicon.

The thin film transistor TFT may be a driving thin film transistor. Although not shown, a switching thin film transistor connected to the driving thin film transistor, a sensing thin film transistor, a storage capacitor, the gate line GL (of FIG. 1) and the data line DL (of FIG. 1) connected to the switching thin film transistor, a power line connected to the driving thin film transistor, a sensing line and a reference line connected to the sensing thin film transistor may be disposed on the substrate 140.

The switching thin film transistor may be switched according to the gate signal of the gate line GL to transmit the data signal of the data line DL to the driving thin film transistor.

The driving thin film transistor may be switched according to the data signal through the switching thin film transistor to transmit a current due to a high level voltage of the power line to the light emitting diode LED.

The sensing thin film transistor may be switched according to a sensing signal of the sensing line to transmit a reference voltage to the driving thin film transistor or to detect a voltage of the driving thin film transistor.

The storage capacitor may keep the data signal through the switching thin film transistor for one frame.

An interlayer insulating layer 142 is disposed on the thin film transistor TFT, and a first electrode 144 is disposed on the interlayer insulating layer 142 in each of the red, green and blue subpixels SPr, SPg and SPb.

For example, the interlayer insulating layer 142 may include an inorganic insulating material such as silicon oxide (SiOx) and silicon nitride (SiNx) or an organic insulating material such as acrylic resin, epoxy resin, phenolic resin, polyamide resin and polyimide resin and may have a single layer or a multiple layer.

The first electrode 144 is connected to the thin film transistor TFT through a contact hole in the interlayer insulating layer 142.

For example, the first electrode 144 may include a transparent conductive material, a half transmissive material or a metallic material having a relatively high reflectance.

When the OLED display device 110 has a top emission type, the first electrode 144 may have a structure having a relatively high reflectance. For example, the first electrode 144 may include a triple layer (Ti/Al/Ti) of titanium (Ti), aluminum (Al) and titanium (Ti), a triple layer (ITO/AI/ITO) of indium tin oxide (ITO), aluminum (Al) and indium tin oxide (ITO) or a triple layer (ITO/Ag alloy/ITO) of indium tin oxide (ITO), silver (Ag) alloy and indium tin oxide (ITO). The silver (Ag) alloy may include an alloy of silver palladium copper (Ag—Pd—Cu: APC).

The first electrode 144 may be an anode.

A bank layer 146 is disposed on the first electrode 144, and a trench TRE is formed in the bank layer 146 and the interlayer insulating layer 142 at a border region between the red, green and blue subpixels SPr, SPg and SPb.

The bank layer 146 covers an edge portion of the first electrode 144 and has an opening exposing a central portion of the first electrode 144. The central portion of the first electrode 144 exposed through the opening of the bank layer 146 may be defined as an emission area, and the other portion except for the emission area may be defined as a non-emission area.

Although the bank layer 146 is disposed to expose the trench TRE in a first aspect of FIGS. 2 and 3, the bank layer 146 may be consecutively disposed between the adjacent subpixels to cover the trench TRE.

For example, the bank layer 146 may include an inorganic insulating material such as silicon oxide (SiOx) and silicon nitride (SiNx) or an organic insulating material such as acrylic resin, epoxy resin, phenolic resin, polyamide resin and polyimide resin and may have a single layer or a multiple layer.

The trench TRE may divide a charge generating layer 150 into the adjacent subpixels in a subsequent process to minimize a lateral leakage current.

A first stack 148, a charge generating layer (CGL) 150, a second stack 152 and a second electrode 154 are sequentially disposed on the bank layer 146 and the first electrode 144 exposed through the opening of the bank layer 146. The first stack 148, the charge generating layer 150 and the second stack 152 constitute an emitting layer, and the first electrode 144, the first stack 148, the charge generating layer 150, the second stack 152 and the second electrode 154 constitute a light emitting diode LED.

The first stack 148 may include a hole injecting layer (HIL), a hole transporting layer (HTL), an emitting material layer (EML) and an electron transporting layer (ETL), and the emitting material layer of the first stack 148 may emit one of a red colored light, a green colored light, a blue colored light and a yellow colored light.

The charge generating layer 150 may include a negative type charge generating layer for supplying an electron to the first stack 148 and a positive type charge generating layer for supplying a hole to the second stack 152.

The second stack 152 may include a hole transporting layer, an emitting material layer, an electron transporting layer and an electron injecting layer, and the emitting material layer of the second stack 152 may emit one of a red colored light, a green colored light, a blue colored light and a yellow colored light.

The emitting material layer of the second stack 152 may emit a light of a color different from a color of a light emitted from the emitting material layer of the first stack 148. For example, the emitting material layer of the first stack 148 may emit a blue colored light and the emitting material layer of the second stack 152 may emit a yellow colored light. Alternatively, the emitting material layer of the first stack 148 may emit a blue colored light and the emitting material layer of the second stack 152 may emit a red colored light and a green colored light.

The second electrode 154 may include a transparent conductive material, a half transmissive metallic material or a metallic material having a relatively high reflectance.

When the OLED display device 110 has a top emission type, the second electrode 154 may have a transparency. For example, the second electrode 154 may include a transparent conductive oxide (TCO) such as indium tin oxide (ITO) and indium zinc oxide (IZO) or a semi-transmissive conductive material such as magnesium (Mg), silver (Ag) and an alloy of magnesium silver (MgAg).

The second electrode 154 may be a cathode.

At least one of the first stack 148, the charge generating layer 150 and the second stack 152 is divided into the red, green and blue subpixels SPr, SPg and SPb and does not contact over the trench TRE due to a step difference of the trench TRE. For example, the charge generating layer 150 or the charge generating layer 150 and at least one of the first stack 148 and the second stack 152 may be divided over the trench TRE.

Further, the second electrode 154 is not divided over the trench TRE even by the step difference of the trench TRE to be connected between the red, green and blue subpixels SPr, SPg and SPb.

For example, a thickness of the charge generating layer 150 may be reduced from a sidewall of the trench TRE to the substrate 140 to be cut.

In the OLED display device 110 according to a first aspect of the present disclosure, the charge generating layer 150 between the adjacent two of the red, green and blue subpixels SPr, SPg and SPb is divided over the trench TRE to be separated from each other. As a result, a lateral leakage current between the adjacent two of the red, green and blue subpixels SPr, SPg and SPb emitting a light of the different colors may be reduced or minimized.

A passivation layer 156 is disposed on the second electrode 154, and an encapsulating layer 160 is disposed on the passivation layer 156.

For example, the passivation layer 156 may include an inorganic insulating material such as aluminum oxide (AlOx), silicon oxide (SiOx) and silicon nitride (SiNx).

The encapsulating layer 160 may have a single layer of an inorganic insulating material or a multiple layer of an inorganic insulating material and an organic insulating material. When the encapsulating layer 160 has a multiple layer, the encapsulating layer 160 may include an inorganic insulating material layer, an organic insulating material layer and an inorganic insulating material layer sequentially disposed.

For example, the encapsulating layer 160 may include an inorganic insulating material such as silicon oxide (SiOx) and silicon nitride (SiNx) or an organic insulating material such as acrylic resin and epoxy resin.

The passivation layer 156 and the encapsulating layers 160 may block a moisture and an oxygen of an exterior.

A black matrix 162 is disposed in a border region between the red, green and blue subpixels SPr, SPg and SPb on the encapsulating layer 160, and red, green and blue color filters 164r, 164g and 164b are disposed in the red, green and blue subpixels SPr, SPg and SPb, respectively, on the encapsulating layer 160. The red, green and blue color filters 164r, 164g and 164b constitute a color filter layer.

The black matrix 162 may cover an edge portion of each of the red, green and blue subpixels SPr, SPg and SPb and expose a central portion of each of the red, green and blue subpixels SPr, SPg and SPb to have a matrix shape. The red, green and blue color filters 164r, 164g and 164b may be disposed in the central portions of the red, green and blue subpixels SPr, SPg and SPb, respectively, to correspond to the opening of the bank layer 146.

For example, the black matrix 162 may include an organic insulating material or an inorganic insulating material having a relatively high absorbance and a relatively low transmittance or an opaque metallic material such as molybdenum (Mo) and titanium (Ti).

Since the black matrix 162 is formed to have a thickness greater than a thickness of the red, green and blue color filters 164r, 164g and 164b, a well effect (or a dam effect) such that red, green and blue color filter material layers have a uniform thickness regardless of existence of the adjacent color filter material layer may be caused during a coating of a color filter material. As a result, the color filter material layers of the red, green and blue subpixels SPr, SPg and SPb may have substantially the same thickness as each other.

The red, green and blue color filters 164r, 164g and 164b have first, second and third thicknesses t1, t2 and t3, respectively, and a side wall of the black matrix 162 has a fourth thickness t4. The first, second and third thicknesses t1, t2 and t3 of the red, green and blue color filters 164r, 164g and 164b may have substantially the same as each other, and the fourth thickness t4 of the black matrix 162 may be greater than each of the first, second and third thicknesses t1, t2 and t3 of the red, green and blue color filters 164r, 164g and 164b.

For example, the first, second and third thicknesses t1, t2 and t3 may be the same as each other (t1=t2=t3), and the fourth thickness t4 may be equal to or greater than about 1.2 times of the first thickness t1 and equal to or smaller than about 2.0 times of the first thickness t1 ((1.2)*t1≤t4≤(2.0)*t1). A first width w1 of the side wall of the black matrix 162 may be equal to or smaller than about 1 μm.

Since each of the red, green and blue color filters 164r, 164g and 164b is disposed to correspond to the opening of the bank layer 146 and the black matrix 162 is disposed to correspond to the bank layer 146, a light emitted from the non-emission area is absorbed and blocked by the black matrix 162 and an abnormal emission of the non-emission area is reduced or minimized.

A microlens 166 is disposed over each of the red, green and blue color filters 164r, 164g and 164b, and an overcoat layer 168 is disposed on the microlens 166. The microlenses 166 of the red, green and blue subpixels SPr, SPg and SPb constitute a microlens array.

The microlens 166 has a half cylindrical shape disposed along a horizontal direction or a vertical direction in each subpixel of the display panel 135. The microlens 166 may have a half spherical shape in another aspect.

The microlens 166 may be formed through a coating step, an exposure step, a developing step and a heat treatment step of an organic insulating material. Since the red, green and blue color filters 164r, 164g and 164b have substantially the same thickness as each other and a step difference is not generated, the organic insulating material for the microlens 166 does not flow down along the step difference during the heat treatment step. As a result, the half cylindrical shape of the microlens 166 is maintained without deformation.

The overcoat layer 168 planarizes a step difference of the black matrix 162 and the microlens 166. The overcoat layer 168 may have a refractive index smaller than a refractive index of the microlens 166 such that the microlens 166 functions as a convex lens.

As a result, a light emitted from the light emitting diode LED passes through the red, green and blue color filters 164r, 164g and 164b and then is concentrated by the microlens 166 so that a light extraction efficiency may be improved.

For the black matrix 162 not to interrupt concentration of the light toward a front direction of the display panel 135, the microlens 166 is exposed outside the black matrix 162.

An apex of the microlens 166 may be disposed higher than a top surface of the sidewall of the black matrix 162.

For example, sums (t1+t5, t2+t5, t3+t5) of the first, second and third thicknesses t1, t2 and t3 of the red, green and blue color filters 164r, 164g and 164b and a fifth thickness t5 of a maximum thickness of the microlens 166 may be equal to or greater than about 1.5 times of the fourth thickness t4 of the black matrix 162 ((t1+t5)≥(1.5)*t4, (t2+t5)≥(1.5)*t4, (t3+t5)≥(1.5)*t4). Further, the fifth thickness t5 may be equal to or greater than about 0.3 times of a second width w2 of the microlens 166 and equal to or smaller than about 2.0 times of the second width w2 of the microlens 166 ((0.3)*w2≤t5≤(2.0)*w2).

In the OLED display device 110 according to a first aspect of the present disclosure, since the black matrix 162 is disposed in the border region between the red, green and blue subpixels SPr, SPg and SPb and the red, green and blue color filters 164r, 164g and 164b having a thickness smaller than a thickness of the black matrix 162 are disposed in the red, green and blue subpixels SPr, SPg and SPb, respectively, the step difference between the red, green and blue color filters 164r, 164g and 164b is reduced and the shape of the microlens 166 is maintained without deformation. As a result, the light extraction efficiency is improved.

Further, since the black matrix 162 is disposed to correspond to the bank layer 146, the light emitted from the non-emission area is absorbed and blocked by the black matrix 162 and the abnormal emission due to the non-emission area is reduced and minimized.

Reduction of the abnormal emission due to the black matrix 162 will be described with reference to drawings.

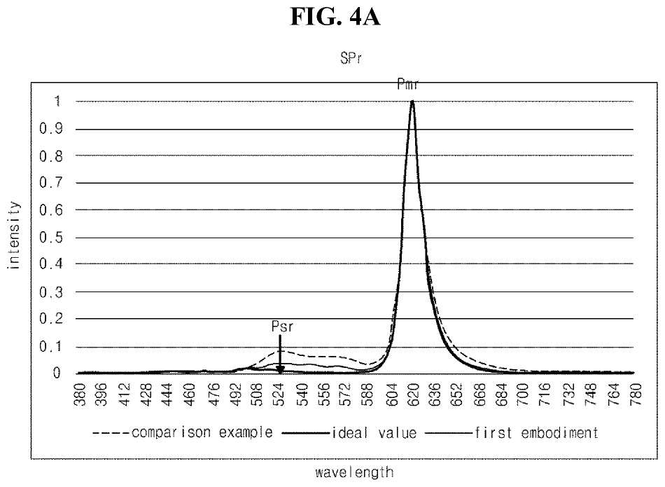

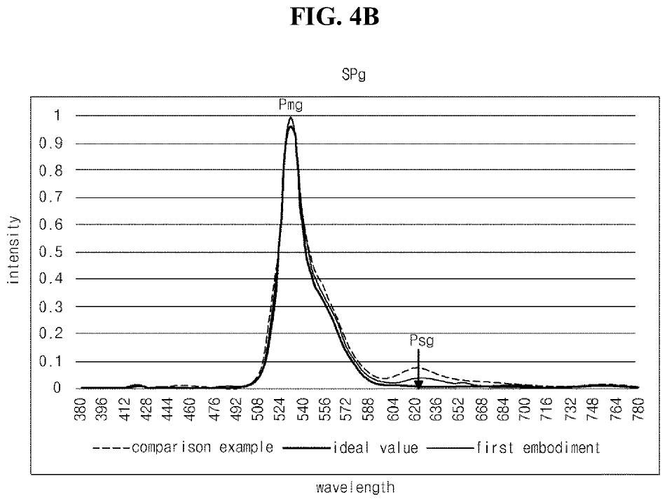

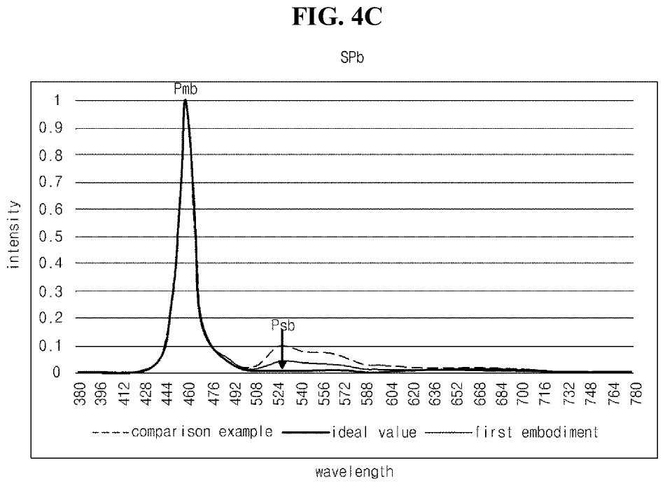

FIGS. 4A, 4B and 4C are views showing spectrums of lights emitted from red, green and blue subpixels, respectively, of an organic light emitting diode display device according to a first aspect of the present disclosure.

In FIG. 4A, an ideal red colored light has a red main peak Pmr corresponding to a red color and does not have a red sub peak Psr spaced apart from the red main peak Pmr.

Each of a light emitted from a red subpixel of an OLED display device of a comparison example where a black matrix is not disposed between adjacent subpixels and a light emitted from the red subpixel SPr of the OLED display device 110 according to a first aspect of the present disclosure has a red main peak Pmr corresponding to a red color and a red sub peak Psr spaced apart from the red main peak Pmr. When the red main peak Pmr has an intensity of about 1, the red sub peak Psr of a comparison example has an intensity of about 0.08 and the red sub peak Psr of a first aspect of the present disclosure has an intensity of about 0.04.

In the OLED display device 110 according to a first aspect of the present disclosure, since the light emitted from the non-emission area of the red subpixel SPr is absorbed and blocked by the black matrix 162, the intensity of the red sub peak Psr is reduced and the abnormal emission due to the non-emission area is reduced and minimized as compared with the comparison example.

In FIG. 4B, an ideal green colored light has a green main peak Pmg corresponding to a green color and does not have a green sub peak Psg spaced apart from the green main peak Pmg.

Each of a light emitted from a green subpixel of an OLED display device of a comparison example where a black matrix is not disposed between adjacent subpixels and a light emitted from the green subpixel SPg of the OLED display device 110 according to a first aspect of the present disclosure has a green main peak Pmg corresponding to a green color and a green sub peak Psg spaced apart from the green main peak Pmg. When the green main peak Pmg has an intensity of about 1, the green sub peak Psg of a comparison example has an intensity of about 0.075 and the green sub peak Psg of a first aspect of the present disclosure has an intensity of about 0.04.

In the OLED display device 110 according to a first aspect of the present disclosure, since the light emitted from the non-emission area of the green subpixel SPg is absorbed and blocked by the black matrix 162, the intensity of the green sub peak Psg is reduced and the abnormal emission due to the non-emission area is reduced and minimized as compared with the comparison example.

In FIG. 4C, an ideal blue colored light has a blue main peak Pmb corresponding to a blue color and does not have a blue sub peak Psb spaced apart from the blue main peak Pmb.

Each of a light emitted from a blue subpixel of an OLED display device of a comparison example where a black matrix is not disposed between adjacent subpixels and a light emitted from the blue subpixel SPb of the OLED display device 110 according to a first aspect of the present disclosure has a blue main peak Pmb corresponding to a blue color and a blue sub peak Psb spaced apart from the blue main peak Pmb. When the blue main peak Pmb has an intensity of about 1, the blue sub peak Psb of a comparison example has an intensity of about 0.1 and the blue sub peak Psb of a first aspect of the present disclosure has an intensity of about 0.04.

In the OLED display device 110 according to a first aspect of the present disclosure, since the light emitted from the non-emission area of the blue subpixel SPb is absorbed and blocked by the black matrix 162, the intensity of the blue sub peak Psb is reduced and the abnormal emission due to the non-emission area is reduced and minimized as compared with the comparison example.

In another aspect, reflection of an external light may be reduced by disposing an irregular reflection pattern on a black matrix. The irregular reflection pattern will be described with reference to a drawing.

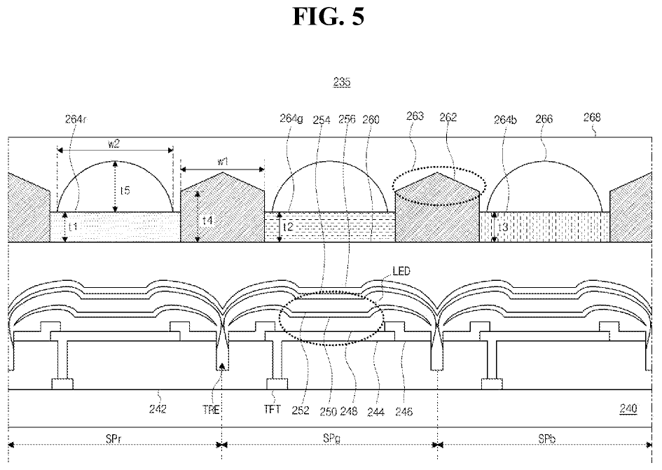

FIG. 5 is a cross-sectional view showing an organic light emitting diode display device according to a second aspect of the present disclosure. Illustration on a part the same as that of a first aspect will be omitted.

In FIG. 5, a display panel 235 of an organic light emitting diode (OLED) display device 210 according to a second aspect of the present disclosure includes red, green and blue subpixels SPr, SPg and SPb, and each of the red, green and blue subpixels SPr, SPg and SPb includes a thin film transistor TFT and a light emitting diode LED.

The thin film transistor TFT is disposed in each of the red, green and blue subpixels SPr, SPg and SPb on a substrate 240, an interlayer insulating layer 242 is disposed on the thin film transistor TFT, and a first electrode 244 is disposed on the interlayer insulating layer 242 in each of the red, green and blue subpixels SPr, SPg and SPb.

The first electrode 244 is connected to the thin film transistor TFT through a contact hole in the interlayer insulating layer 242, and the first electrode 244 may be an anode.

A bank layer 246 is disposed on the first electrode 244, and a trench TRE is formed in the bank layer 246 and the interlayer insulating layer 242 at a border region between the red, green and blue subpixels SPr, SPg and SPb.

The bank layer 246 covers an edge portion of the first electrode 244 and has an opening exposing a central portion of the first electrode 244. The central portion of the first electrode 244 exposed through the opening of the bank layer 246 may be defined as an emission area, and the other portion except for the emission area may be defined as a non-emission area.

A first stack 248, a charge generating layer (CGL) 250, a second stack 252 and a second electrode 254 are sequentially disposed on the bank layer 246 and the first electrode 244 exposed through the opening of the bank layer 246. The first stack 248, the charge generating layer 250 and the second stack 252 constitute an emitting layer, and the first electrode 244, the first stack 248, the charge generating layer 250, the second stack 252 and the second electrode 254 constitute a light emitting diode LED.

Each of the first and second stacks 248 and 252 may include a hole injecting layer (HIL), a hole transporting layer (HTL), an emitting material layer (EML) and an electron transporting layer (ETL), the charge generating layer 250 may include a negative type charge generating layer and a positive type charge generating layer, and the second electrode 254 may be a cathode.

A passivation layer 256 is disposed on the second electrode 254, and an encapsulating layer 260 is disposed on the passivation layer 256.

A black matrix 262 is disposed in a border region between the red, green and blue subpixels SPr, SPg and SPb on the encapsulating layer 260, and red, green and blue color filters 264r, 264g and 264b are disposed in the red, green and blue subpixels SPr, SPg and SPb, respectively, on the encapsulating layer 260. The red, green and blue color filters 264r, 264g and 264b constitute a color filter layer.

The black matrix 262 may cover an edge portion of each of the red, green and blue subpixels SPr, SPg and SPb and may expose a central portion of each of the red, green and blue subpixels SPr, SPg and SPb to have a matrix shape. The red, green and blue color filters 264r, 264g and 264b may be disposed in the central portions of the red, green and blue subpixels SPr, SPg and SPb, respectively, to correspond to the opening of the bank layer 246.

For example, the black matrix 262 may include an organic insulating material or an inorganic insulating material having a relatively high absorbance and a relatively low transmittance or an opaque metallic material such as molybdenum (Mo) and titanium (Ti).

An irregular reflection pattern 263 is disposed on a top surface of the black matrix 262. The irregular reflection pattern 263 may have a convex shape having a triangular cross-section.

In another aspect, the irregular reflection pattern 263 may have a concave shape having a triangular cross-section or a convex shape having a trapezoidal cross-section.

Since the irregular reflection pattern 263 reflects an external light incident to the display panel 235 toward various directions, reflection of an external light is reduced and deterioration of a display quality due to reflection of an external light is prevented.

Since the black matrix 262 is formed to have a thickness greater than a thickness of the red, green and blue color filters 264r, 264g and 264b, a well effect (or a dam effect) such that red, green and blue color filter material layers have a uniform thickness regardless of existence of the adjacent color filter material layer may be caused during a coating of a color filter material. As a result, the color filter material layers of the red, green and blue subpixels SPr, SPg and SPb may have substantially the same thickness as each other.

The red, green and blue color filters 264r, 264g and 264b have first, second and third thicknesses t1, t2 and t3, respectively, and a side wall of the black matrix 262 has a fourth thickness t4. The first, second and third thicknesses t1, t2 and t3 of the red, green and blue color filters 264r, 264g and 264b may have substantially the same as each other, and the fourth thickness t4 of the black matrix 262 may be greater than each of the first, second and third thicknesses t1, t2 and t3 of the red, green and blue color filters 264r, 264g and 264b.

For example, the first, second and third thicknesses t1, t2 and t3 may be the same as each other (t1=t2=t3), and the fourth thickness t4 may be equal to or greater than about 1.2 times of the first thickness t1 and equal to or smaller than about 2.0 times of the first thickness t1 ((1.2)*t1≤t4≤(2.0)*t1). A first width w1 of the black matrix 262 may be equal to or smaller than about 1 μm.

Since each of the red, green and blue color filters 264r, 264g and 264b is disposed to correspond to the opening of the bank layer 246 and the black matrix 262 is disposed to correspond to the bank layer 246, a light emitted from the non-emission area is absorbed and blocked by the black matrix 262 and an abnormal emission of the non-emission area is reduced or minimized.

A microlens 266 is disposed over each of the red, green and blue color filters 264r, 264g and 264b, and an overcoat layer 268 is disposed on the microlens 266. The microlenses 266 of the red, green and blue subpixels SPr, SPg and SPb constitute a microlens array.

The microlens 266 has a half cylindrical shape disposed along a horizontal direction or a vertical direction in each subpixel of the display panel 235. The microlens 266 may have a half spherical shape in another aspect.

The microlens 266 may be formed through a coating step, an exposure step, a developing step and a heat treatment step of an organic insulating material. Since the red, green and blue color filters 264r, 264g and 264b have substantially the same thickness as each other and a step difference is not generated, the organic insulating material for the microlens 266 does not flow down along the step difference during the heat treatment step. As a result, the half cylindrical shape or the half spherical shape of the microlens 266 is maintained without deformation.

The overcoat layer 268 planarizes a step difference of the black matrix 262 and the microlens 266. The overcoat layer 268 may have a refractive index smaller than a refractive index of the microlens 266 such that the microlens 266 functions as a convex lens.

As a result, a light emitted from the light emitting diode LED passes through the red, green and blue color filters 264r, 264g and 264b and then is concentrated by the microlens 266 so that a light extraction efficiency may be improved.

For the black matrix 262 not to interrupt concentration of the light toward a front direction of the display panel 235, the microlens 266 is exposed outside the black matrix 262.

An apex of the microlens 266 may be disposed higher than a top surface of the sidewall of the black matrix 262.

For example, sums (t1+t5, t2+t5, t3+t5) of the first, second and third thicknesses t1, t2 and t3 of the red, green and blue color filters 264r, 264g and 264b and a fifth thickness t5 of a maximum thickness of the microlens 266 may be equal to or greater than about 1.5 times of the fourth thickness t4 of the black matrix 262 ((t1+t5)≥(1.5)*t4, (t2+t5)≥(1.5)*t4, (t3+t5)≥(1.5)*t4). Further, the fifth thickness t5 may be equal to or greater than about 0.3 times of a second width w2 of the microlens 266 and equal to or smaller than about 2.0 times of the second width w2 of the microlens 266 ((0.3)*w2≤t5≤(2.0)*w2).

In the OLED display device 210 according to a second aspect of the present disclosure, since the black matrix 262 is disposed in the border region between the red, green and blue subpixels SPr, SPg and SPb and the red, green and blue color filters 264r, 264g and 264b having a thickness smaller than a thickness of the black matrix 262 are disposed in the red, green and blue subpixels SPr, SPg and SPb, respectively, the step difference between the red, green and blue color filters 264r, 264g and 264b is reduced and the shape of the microlens 266 is maintained without deformation. As a result, the light extraction efficiency is improved.

Further, since the black matrix 262 is disposed to correspond to the bank layer 246, the light emitted from the non-emission area is absorbed and blocked by the black matrix 262 and the abnormal emission due to the non-emission area is reduced and minimized.

In addition, since the irregular reflection pattern 263 having a convex shape or a concave shape is disposed on the top surface of the black matrix 262, reflection of the external light is reduced and deterioration of the display quality due to reflection of the external light is prevented.

In another aspect, a light extraction efficiency may be improved by disposing an auxiliary lens at a periphery of a microlens. The auxiliary lens will be described with reference to a drawing.

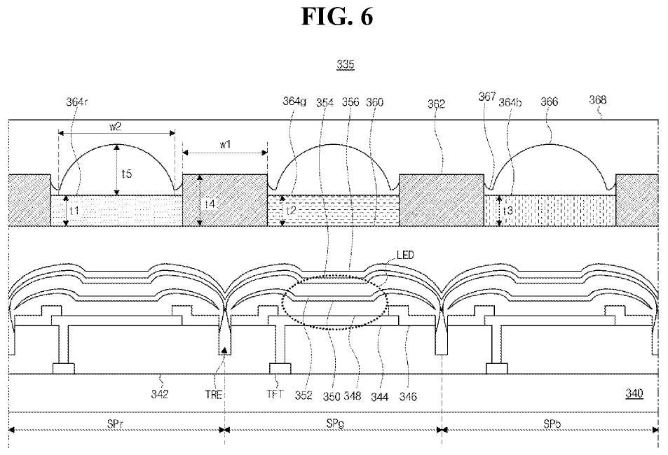

FIG. 6 is a cross-sectional view showing an organic light emitting diode display device according to a third aspect of the present disclosure. Illustration on a part the same as that of first and second aspects will be omitted.

In FIG. 6, a display panel 335 of an organic light emitting diode (OLED) display device 310 according to a third aspect of the present disclosure includes red, green and blue subpixels SPr, SPg and SPb, and each of the red, green and blue subpixels SPr, SPg and SPb includes a thin film transistor TFT and a light emitting diode LED.

The thin film transistor TFT is disposed in each of the red, green and blue subpixels SPr, SPg and SPb on a substrate 340, an interlayer insulating layer 342 is disposed on the thin film transistor TFT, and a first electrode 344 is disposed on the interlayer insulating layer 342 in each of the red, green and blue subpixels SPr, SPg and SPb.

The first electrode 344 is connected to the thin film transistor TFT through a contact hole in the interlayer insulating layer 342, and the first electrode 344 may be an anode.

A bank layer 346 is disposed on the first electrode 344, and a trench TRE is formed in the bank layer 346 and the interlayer insulating layer 342 at a border region between the red, green and blue subpixels SPr, SPg and SPb.

The bank layer 346 covers an edge portion of the first electrode 344 and has an opening exposing a central portion of the first electrode 344. The central portion of the first electrode 344 exposed through the opening of the bank layer 346 may be defined as an emission area, and the other portion except for the emission area may be defined as a non-emission area.

A first stack 348, a charge generating layer (CGL) 350, a second stack 352 and a second electrode 354 are sequentially disposed on the bank layer 346 and the first electrode 344 exposed through the opening of the bank layer 346. The first stack 348, the charge generating layer 350 and the second stack 352 constitute an emitting layer, and the first electrode 344, the first stack 348, the charge generating layer 350, the second stack 352 and the second electrode 354 constitute a light emitting diode LED.

Each of the first and second stacks 348 and 352 may include a hole injecting layer (HIL), a hole transporting layer (HTL), an emitting material layer (EML) and an electron transporting layer (ETL), the charge generating layer 350 may include a negative type charge generating layer and a positive type charge generating layer, and the second electrode 354 may be a cathode.

A passivation layer 356 is disposed on the second electrode 354, and an encapsulating layer 360 is disposed on the passivation layer 356.

A black matrix 362 is disposed in a border region between the red, green and blue subpixels SPr, SPg and SPb on the encapsulating layer 360, and red, green and blue color filters 364r, 364g and 364b are disposed in the red, green and blue subpixels SPr, SPg and SPb, respectively, on the encapsulating layer 360. The red, green and blue color filters 364r, 364g and 364b constitute a color filter layer.

The black matrix 362 may cover an edge portion of each of the red, green and blue subpixels SPr, SPg and SPb and may expose a central portion of each of the red, green and blue subpixels SPr, SPg and SPb to have a matrix shape. The red, green and blue color filters 364r, 364g and 364b may be disposed in the central portions of the red, green and blue subpixels SPr, SPg and SPb, respectively, to correspond to the opening of the bank layer 346.

For example, the black matrix 362 may include an organic insulating material or an inorganic insulating material having a relatively high absorbance and a relatively low transmittance or an opaque metallic material such as molybdenum (Mo) and titanium (Ti).

Since the black matrix 362 is formed to have a thickness greater than a thickness of the red, green and blue color filters 364r, 364g and 364b, a well effect (or a dam effect) such that red, green and blue color filter material layers have a uniform thickness regardless of existence of the adjacent color filter material layer may be caused during a coating of a color filter material. As a result, the color filter material layers of the red, green and blue subpixels SPr, SPg and SPb may have substantially the same thickness as each other.

The red, green and blue color filters 364r, 364g and 364b have first, second and third thicknesses t1, t2 and t3, respectively, and a side wall of the black matrix 362 has a fourth thickness t4. The first, second and third thicknesses t1, t2 and t3 of the red, green and blue color filters 364r, 364g and 364b may have substantially the same as each other, and the fourth thickness t4 of the black matrix 362 may be greater than each of the first, second and third thicknesses t1, t2 and t3 of the red, green and blue color filters 364r, 364g and 364b.

For example, the first, second and third thicknesses t1, t2 and t3 may be the same as each other (t1=t2=t3), and the fourth thickness t4 may be equal to or greater than about 1.2 times of the first thickness t1 and equal to or smaller than about 2.0 times of the first thickness t1 ((1.2)*t1≤t4≤(2.0)*t1). A first width w1 of the side wall of the black matrix 362 may be equal to or smaller than about 1 μm.

Since each of the red, green and blue color filters 364r, 364g and 364b is disposed to correspond to the opening of the bank layer 346 and the black matrix 362 is disposed to correspond to the bank layer 346, a light emitted from the non-emission area is absorbed and blocked by the black matrix 362 and an abnormal emission of the non-emission area is reduced or minimized.

A microlens 366 and an auxiliary lens 367 at both sides of the microlens 366 are disposed over each of the red, green and blue color filters 364r, 364g and 364b, and an overcoat layer 368 is disposed on the microlens 366 and the auxiliary lens 367. The microlenses 366 of the red, green and blue subpixels SPr, SPg and SPb constitute a microlens array.

The microlens 366 has a half cylindrical shape disposed along a horizontal direction or a vertical direction in each subpixel of the display panel 335. The microlens 366 may have a half spherical shape or the half spherical shape in another aspect.

The microlens 366 may be formed through a coating step, an exposure step, a developing step and a heat treatment step of an organic insulating material. Since the red, green and blue color filters 364r, 364g and 364b have substantially the same thickness as each other and a step difference is not generated, the organic insulating material for the microlens 366 does not flow down along the step difference during the heat treatment step. As a result, the half cylindrical shape of the microlens 366 is maintained without deformation.

The auxiliary lens 367 is disposed at a periphery of the microlens 366. For example, the auxiliary lens 367 may be disposed between the black matrix 362 and the microlens 366 to have a concave shape. The auxiliary lens 367 may have a round top surface or a flat top surface.

The overcoat layer 368 planarizes a step difference of the black matrix 362, the microlens 366 and the auxiliary lens 367. The overcoat layer 368 may have a refractive index smaller than a refractive index of the microlens 366 and the auxiliary lens 367 such that the microlens 366 functions as a convex lens and the auxiliary lens 367 functions as a concave lens.

As a result, a light emitted from the light emitting diode LED passes through the red, green and blue color filters 364r, 364g and 364b and then is concentrated by the microlens 366 so that a light extraction efficiency may be improved.

After the light emitted from the light emitting diode LED passes through the red, green and blue color filters 364r, 364g and 364b, an incident angle of the light passing between the black matrix 362 and the microlens 366 with respect to a top surface of the overcoat layer 368 increases due to the auxiliary lens 367. As a result, the light is totally reflected by the top surface of the overcoat layer 368 and is not emitted to an exterior. Accordingly, an influence on the adjacent subpixel due to the light emitted from a gap space between the black matrix 362 and the microlens 366 is reduced and deterioration such as a color mixture is reduced and minimized.

For the black matrix 362 not to interrupt concentration of the light toward a front direction of the display panel 335, the microlens 366 is exposed outside the black matrix 362.

An apex of the microlens 366 may be disposed higher than a top surface of the sidewall of the black matrix 362.

For example, sums (t1+t5, t2+t5, t3+t5) of the first, second and third thicknesses t1, t2 and t3 of the red, green and blue color filters 364r, 364g and 364b and a fifth thickness t5 of a maximum thickness of the microlens 366 may be equal to or greater than about 1.5 times of the fourth thickness t4 of the black matrix 362 ((t1+t5)≥(1.5)*t4, (t2+t5)≥(1.5)*t4, (t3+t5)≥(1.5)*t4). Further, the fifth thickness t5 may be equal to or greater than about 0.3 times of a second width w2 of the microlens 366 and equal to or smaller than about 2.0 times of the second width w2 of the microlens 366 ((0.3)*w2≤t5≤(2.0)*w2).

In the OLED display device 310 according to a third aspect of the present disclosure, since the black matrix 362 is disposed in the border region between the red, green and blue subpixels SPr, SPg and SPb and the red, green and blue color filters 364r, 364g and 364b having a thickness smaller than a thickness of the black matrix 362 are disposed in the red, green and blue subpixels SPr, SPg and SPb, respectively, the step difference between the red, green and blue color filters 364r, 364g and 364b is reduced and the shape of the microlens 366 is maintained without deformation. As a result, the light extraction efficiency is improved.

Further, since the black matrix 362 is disposed to correspond to the bank layer 346, the light emitted from the non-emission area is absorbed and blocked by the black matrix 362 and the abnormal emission due to the non-emission area is reduced and minimized.

In addition, since the auxiliary lens 367 having the concave shape is disposed at a periphery of the microlens 366, the light extraction efficiency is further improved.

In another aspect, a shape of a microlens is maintained by using one of red, green and blue color filters as a sidewall. The one of the red, green and blue color filters used as the sidewall will be described with reference to a drawing.

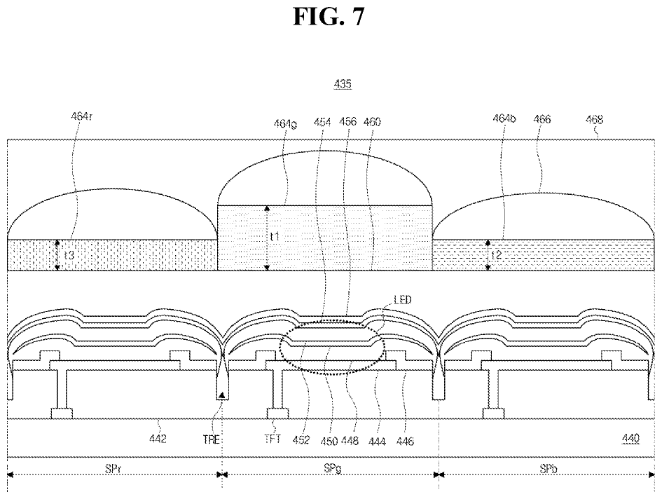

FIG. 7 is a cross-sectional view showing an organic light emitting diode display device according to a fourth aspect of the present disclosure. Illustration on a part the same as that of first to third aspects will be omitted.

In FIG. 7, a display panel 435 of an organic light emitting diode (OLED) display device 410 according to a fourth aspect of the present disclosure includes red, green and blue subpixels SPr, SPg and SPb, and each of the red, green and blue subpixels SPr, SPg and SPb includes a thin film transistor TFT and a light emitting diode LED.

The thin film transistor TFT is disposed in each of the red, green and blue subpixels SPr, SPg and SPb on a substrate 440, an interlayer insulating layer 442 is disposed on the thin film transistor TFT, and a first electrode 444 is disposed on the interlayer insulating layer 442 in each of the red, green and blue subpixels SPr, SPg and SPb.

The first electrode 444 is connected to the thin film transistor TFT through a contact hole in the interlayer insulating layer 442, and the first electrode 444 may be an anode.

A bank layer 446 is disposed on the first electrode 444, and a trench TRE is formed in the bank layer 446 and the interlayer insulating layer 442 at a border region between the red, green and blue subpixels SPr, SPg and SPb.

The bank layer 446 covers an edge portion of the first electrode 444 and has an opening exposing a central portion of the first electrode 444. The central portion of the first electrode 444 exposed through the opening of the bank layer 446 may be defined as an emission area, and the other portion except for the emission area may be defined as a non-emission area.

A first stack 448, a charge generating layer (CGL) 450, a second stack 452 and a second electrode 454 are sequentially disposed on the bank layer 446 and the first electrode 444 exposed through the opening of the bank layer 446. The first stack 448, the charge generating layer 450 and the second stack 452 constitute an emitting layer, and the first electrode 444, the first stack 448, the charge generating layer 450, the second stack 452 and the second electrode 454 constitute a light emitting diode LED.

Each of the first and second stacks 448 and 452 may include a hole injecting layer (HIL), a hole transporting layer (HTL), an emitting material layer (EML) and an electron transporting layer (ETL), the charge generating layer 450 may include a negative type charge generating layer and a positive type charge generating layer, and the second electrode 454 may be a cathode.

A passivation layer 456 is disposed on the second electrode 454, and an encapsulating layer 460 is disposed on the passivation layer 456.

Red, green and blue color filters 464r, 464g and 464b are disposed in the red, green and blue subpixels SPr, SPg and SPb, respectively, on the encapsulating layer 460, a microlens 466 is disposed on each of the red, green and blue color filters 464r, 464g and 464b, and an overcoat layer 468 is disposed on the microlens 466. The red, green and blue color filters 464r, 464g and 464b constitute a color filter layer, and the microlenses 466 of the red, green and blue subpixels SPr, SPg and SPb constitute a microlens array.

Since the red color filter 464r is formed to have a thickness greater than a thickness of each of the green and blue color filters 464g and 464b, a well effect (or a dam effect) such that green and blue color filter material layers have a uniform thickness regardless of existence of the adjacent color filter material layer may be caused during a coating of a color filter material. As a result, the color filter material layers of the green and blue subpixels SPg and SPb may have substantially the same thickness as each other.

The red, green and blue color filters 464r, 464g and 464b have first, second and third thicknesses t1, t2 and t3, respectively. The second and third thicknesses t2 and t3 of the green and blue color filters 464g and 464b may have substantially the same as each other, and the first thickness t1 of the red color filter 464r may be greater than each of the second and third thicknesses t2 and t3 of the green and blue color filters 464g and 464b.

For example, the second and third thicknesses t2 and t3 may be the same as each other (t2=t3), and the first thickness t1 may be equal to or greater than about 1.2 times of the second thickness t2 and equal to or smaller than about 2.0 times of the second thickness t2 ((1.2)*t2≤t1≤(2.0)*t2).

Since the green and blue color filters 464g and 464b are formed to have a uniform thickness without a step difference using the red color filter 464r as a sidewall, a shape of the microlens 466 may be maintained without increase of a fabrication process.

In a fourth aspect, the red color filter 464r having a relatively low influence on an efficiency of the color filter layer exemplarily has a thickness greater than a thickness of each of the green and blue color filters 464g and 464b. In another aspect where an influence on an efficiency of the color filter layer is reduced, one of the green and blue color filters may have a relatively great thickness to function as a sidewall and the other color filters (red and blue color filters, or red and green color filters) may have a relatively small thickness.

The microlens 466 has a half cylindrical shape disposed along a horizontal direction or a vertical direction in each subpixel of the display panel 435. The microlens 466 may have a half spherical shape in another aspect.

The microlens 466 may be formed through a coating step, an exposure step, a developing step and a heat treatment step of an organic insulating material. Since the green and blue color filters 464g and 464b have substantially the same thickness as each other and a step difference is not generated, the organic insulating material for the microlens 466 does not flow down along the step difference during the heat treatment step. As a result, the half cylindrical shape or the half spherical shape of the microlens 466 is maintained without deformation.

The overcoat layer 468 planarizes a step difference of the red, green and blue color filters 464r, 464g and 464b and the microlens 466. The overcoat layer 468 may have a refractive index smaller than a refractive index of the microlens 466 such that the microlens 466 functions as a convex lens.

As a result, a light emitted from the light emitting diode LED passes through the red, green and blue color filters 464r, 464g and 464b and then is concentrated by the microlens 466 so that a light extraction efficiency may be improved.

In the OLED display device 410 according to a fourth aspect of the present disclosure, since the green and blue color filters 464g and 464b having a thickness smaller than a thickness of the red color filter 464r are disposed in the green and blue subpixels SPg and SPb, respectively, the step difference between the green and blue color filters 464g and 464b is reduced and the shape of the microlens 466 is maintained without deformation. As a result, the light extraction efficiency is improved.

Further, since a black matrix is omitted, a fabrication process is simplified and an aperture ratio is enlarged.

Consequently, in the OLED display device according to aspects of the present disclosure, since the black matrix higher than the color filter is disposed between the adjacent color filters, the step difference between the color filters is reduced and the shape of the microlens is maintained. As a result, the abnormal emission of the non-emission area is reduced and minimized.

Further, since one color filter is formed to be higher than the other color filters, the step difference between the other color filters is reduced and the shape of the microlens is maintained. As a result, the fabrication process is simplified.

It will be apparent to those skilled in the art that various modifications and variation may be made in the present disclosure without departing from the scope of the disclosure. Thus, it is intended that the present disclosure cover the modifications and variations of this disclosure, provided they come within the scope of the appended claims and their equivalents.

What is claimed is:

1. An organic light emitting diode display device, comprising:
a substrate having first, second and third subpixels;
a light emitting diode disposed in each of the first, second and third subpixels on the substrate;
a black matrix disposed in a border region between the first, second and third subpixels on the light emitting diode;
first, second and third color filters disposed in the first, second and third subpixels, respectively, on the light emitting diode, a thickness of each of the first, second and third color filters smaller than a thickness of the black matrix; and
a microlens disposed on each of the first, second and third color filters.

2. The organic light emitting diode display device of claim 1, wherein the first, second and third color filters respectively have first, second and third thicknesses, and the black matrix has a fourth thickness,
wherein the first, second and third thicknesses are a same as each other, and
wherein the fourth thickness is equal to or greater than 1.2 times of the first thickness and is equal to or smaller than 2.0 times of the first thickness.

3. The organic light emitting diode display device of claim 1, wherein an apex of the microlens is disposed to be higher than a top surface of the black matrix.

4. The organic light emitting diode display device of claim 3, wherein the first, second and third color filters have first, second and third thicknesses, respectively, the black matrix has a fourth thickness, and the microlens has a fifth thickness being the maximum thickness thereof, and
wherein a sum of each of the first, second and third thicknesses and the fifth thickness is equal to or greater than 1.5 times of the fourth thickness.

5. The organic light emitting diode display device of claim 4, wherein the microlens has a microlens width, and
wherein the fifth thickness is equal to or greater than 0.3 times of the microlens width and is equal to or smaller than 2.0 times of the microlens width.

6. The organic light emitting diode display device of claim 1, wherein the microlens has one of a half cylindrical shape and a half spherical shape.

7. The organic light emitting diode display device of claim 1, further comprising an irregular reflection pattern disposed on the black matrix.

8. The organic light emitting diode display device of claim 7, wherein the irregular reflection pattern has one of a convex shape having a triangular cross-section, a convex shape having a trapezoidal cross-section and a concave shape having a triangular cross-section.

9. The organic light emitting diode display device of claim 1, further comprising an auxiliary lens at a periphery of the microlens.

10. The organic light emitting diode display device of claim 9, wherein the auxiliary lens is disposed between the black matrix and the microlens to have a concave shape.

11. The organic light emitting diode display device of claim 9, further comprising an overcoat layer on the microlens and the auxiliary lens and having a refractive index smaller than a refractive index of the microlens and the auxiliary lens.

12. The organic light emitting diode display device of claim 1, further comprising an overcoat layer on the microlens and having a refractive index smaller than a refractive index of the microlens.

13. The organic light emitting diode display device of claim 1, further comprising a bank layer having an opening exposing an emission area of each of the first, second and third subpixels, wherein each of the first, second and third color filters is disposed to correspond to the opening of the bank layer and the black matrix is disposed to correspond to the bank layer.

14. An organic light emitting diode display device, comprising:
a substrate having first, second and third subpixels;
a light emitting diode disposed in each of the first, second and third subpixels on the substrate;
first, second and third color filters disposed in the first, second and third subpixels, respectively, on the light emitting diode; and
a microlens disposed on each of the first, second and third color filters,
wherein a thickness of one of the first, second and third color filters is greater than a thickness of two of the first, second and third color filters.

15. The organic light emitting diode display device of claim 14, wherein the first, second and third color filters respectively have first, second and third thicknesses,
wherein the second and third thicknesses are a same as each other, and
wherein the first thickness is equal to or greater than 1.2 times of the second thickness and is equal to or smaller than 2.0 times of the second thickness.

16. The organic light emitting diode display device of claim 14, further comprising an overcoat layer on the microlens and having a refractive index smaller than a refractive index of the microlens.
